(19) United States
(12) Patent Application Publication
(10) Pub. No.: US 2014/0240904 A1
(43) Pub. Date: Aug. 28, 2014

(54) PROTECTING STRUCTURE OF UNINTERRUPTIBLE POWER SUPPLY

(71) Applicant: DELTA ELECTRONICS, INC., Taoyuan County (TW)

(72) Inventors: Jen-Chuan LIAO, Taoyuan County (TW); Hong-Jing LING, Taoyuan County (TW); Shu-Ken LIN, Taoyuan County (TW)

(73) Assignee: DELTA ELECTRONICS, INC., Taoyuan County (TW)

(21) Appl. No.: 14/020,093

(22) Filed: Sep. 6, 2013

(30) Foreign Application Priority Data
Feb. 22, 2013 (CN) 201310057194.4

(51) Int. Cl. H05K 5/00

(52) U.S. Cl. CPC H05K 5/00
USPC 361/679.01

(57) ABSTRACT

A protecting structure of an uninterruptible power supply prevents the uninterruptible power supply. The uninterruptible power supply device has a switch with a switching piece. The protecting structure includes a chassis, a sensor and a cover body. The chassis has an opening slot, the uninterruptible power supply device is installed in the chassis, and the switching piece is disposed corresponding to the opening slot. The sensor is provided on a side of the opening slot of the chassis and electrically connected with the uninterruptible power supply device. The cover body includes a cover plate and at least one blocking member connecting with the cover plate. The cover plate covers the opening slot, wherein the switching piece ejects the blocking member to expose the opening slot when the covered switching piece is switched from a first position to a second position.

### BACKGROUND OF THE INVENTION

1. Field of the Invention

The present invention generally relates to a protecting structure and, in particular to a protecting structure of uninterruptible power supply for preventing the uninterruptible power supply from a faulty operation.

2. Description of Related Art

Nowadays a traditional uninterruptible power supply is designed to switch a splitter into a normal loop status or a bypass loop status by controlling a switch of the splitter. However, power controlling device provides electricity to electronic instruments or production equipment through a splitter for choosing a proper loop and achieving an uninterrupted power supply.

A conventional uninterruptible power supply is designed to have a splitter on the outside of an electronic instrument or production equipment etc. The splitter has a switch, and the switch is provided with a switching element. When the switching element is not pulled, the splitter is in a normal loop status, and the electricity of the power supply device will be provided to the electronic instrument or production equipment from the normal loop. Furthermore, when the switching element is pulled, the splitter will be switched from a normal loop status to a bypass loop state, and the electricity of the power supply device will be provided to electronic instrument or production equipment through the bypass loop.

A conventional uninterruptible power supply has the following shortcomings: firstly, a sensor component of the switching element of the switch is provided with the splitter together so that the splitter is expensive; secondly, the splitter is installed on the outside of the chassis that a faulty operation might be happened; thirdly, as the splitter is installed on the outside of the chassis, an occupied space of the chassis is increased.

In view of the above drawbacks, the Inventor proposes the present invention based on his expert knowledge and elaborate researches in order to solve the problems of related art.

### SUMMARY OF THE INVENTION

Accordingly, an object of the present invention is to provide a protecting structure of an uninterruptible power supply. It utilizes a cover to cover an opening slot, and a blocking member is ejected by a switching piece that a faulty operation can be avoided and an effect of protecting uninterruptible power device will be achieved.

In order to achieve the object mentioned above, the present invention provides a protecting structure of an uninterruptible power supply. The protecting structure is used in a switch having a switching piece. The protecting structure includes a chassis and a cover body. The chassis has an opening slot, the switch is installed in the chassis, and the switching piece is disposed correspondingly to the opening slot. The cover body includes a cover plate and at least one blocking member connecting with the cover plate. And the cover plate covers the opening slot, wherein the switching piece ejects the blocking member to expose the opening slot when the covered switching piece is switched from a first position to a second position.

In order to achieve the object mentioned above, the present invention provides a protecting structure of an uninterruptible power supply. The protecting structure is used in an uninterruptible power supply device with a switch having a switching piece. The protecting structure includes a chassis, a sensor and a cover body. The chassis has an opening slot, the uninterruptible power supply device is installed in the chassis, and the switching piece is disposed correspondingly to the opening slot. The sensor is provided on a side of the opening slot of the chassis and is electrically connected with the uninterruptible power supply device. The cover body includes a cover plate and at least one blocking member connecting with the cover plate. And the cover plate covers the opening slot, wherein the switching piece ejects the blocking member to expose the opening slot when the covered switching piece is switched from a first position to a second position.

The present invention has the following effects. Firstly, the sensor can be provided separately with the uninterruptible power supply device by disposing on the supporting plate. Thus an uninterruptible power supply device without a sensor can be chosen, and the uninterruptible power supply device will be cheaper for cost-saving. Secondly, as the switch is disposed correspondingly in the opening slot and the uninterruptible power supply device is installed in the cabinet, a size of electronic instrument or production equipment installed with the uninterruptible power supply device might be reduced. Thirdly, the cover plate is screwed with the chassis by a fastener that the cover plate will not detach from the chassis when the cover plate suffers an external force. Fourthly, the cover plate will be fixed firmly on the chassis by a hook clipped in the engaging slot. Hence the cover plate will not detach from the chassis when the cover plate suffers an external force.

### BRIEF DESCRIPTION OF DRAWING

The features of the invention believed to be novel are set forth with particularity in the appended claims. The invention itself, however, may be best understood by reference to the following detailed description of the invention, which describes a number of exemplary embodiments of the invention, taken in conjunction with the accompanying drawings, in which:

FIG. 1 is an explosion perspective view of a first embodiment of the present invention;

FIG. 2 is a schematic view showing the operating state of a first embodiment of the present invention;

FIG. 3 is another schematic view showing the operating state of a first embodiment of the present invention;

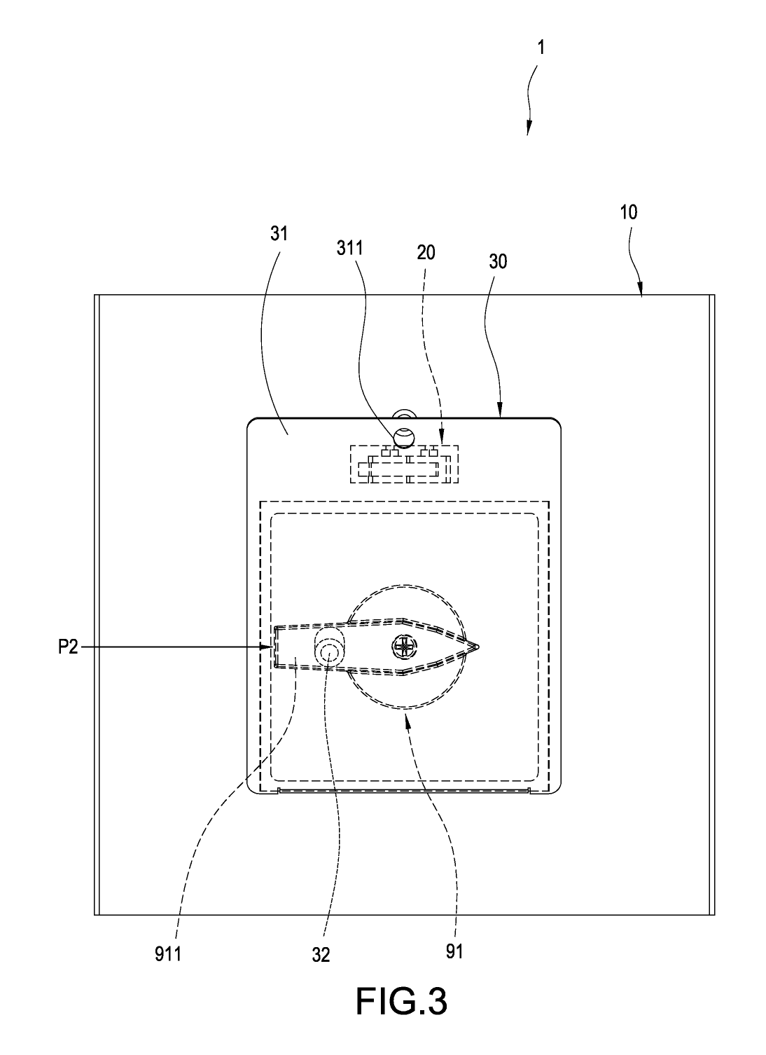

FIG. 4 is a further schematic view showing the operating state of a first embodiment of the present invention;

FIG. 5 is further another schematic view showing the operating state of a first embodiment of the present invention;

FIG. 6 is a schematic view of a second embodiment of the present invention.

FIG. 7 is a schematic view showing the operating state of a third embodiment of the present invention;

FIG. 8 is another schematic view showing the operating state of a third embodiment of the present invention;

FIG. 9 is a schematic view showing the operating state of a fourth embodiment of the present invention;

FIG. 10 is another schematic view showing the operating state of a fourth embodiment of the present invention.

### DETAILED DESCRIPTION OF THE PREFERRED EMBODIMENTS

In cooperation with attached drawings, the technical contents and detailed description of the invention are described thereinafter according to a number of preferable embodiments, being not used to limit its executing scope. Any equivalent variation and modification made according to appended claims is all covered by the claims claimed by the present invention.

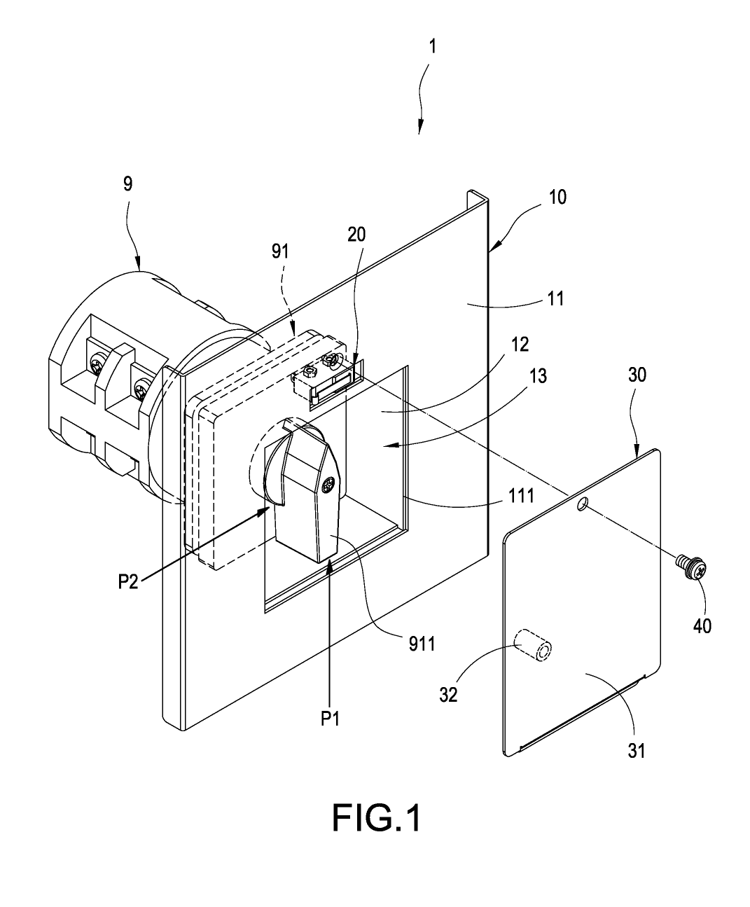

Please refer to FIG. 1, it depicts an explosion perspective view of a first embodiment of the present invention. The present invention provides a protecting structure 1 of an uninterruptible power supply device 9 for preventing the uninterruptible power supply device 9 from a faulty operation. The protecting structure 1 is used for an uninterruptible power supply device 9. The protecting structure 1 includes a chassis 10, a sensor 20 and a cover body 30.

The uninterruptible power supply device 9 could be a circuit breaker, a contactor, a relay or a splitter. The uninterruptible power supply device 9 has a switch 91 with a switching element 911, and the uninterruptible power supply device 9 can switch from a first position P1 to a second position P2 by pulling the switching piece 911 of the switch 91 for the uninterruptible power supply device 9 switching alternately between a first state and a second state, wherein the first state is a normal loop status and the second state is a bypass loop status. Besides, the uninterruptible power supply device 9 further includes a starting switch.

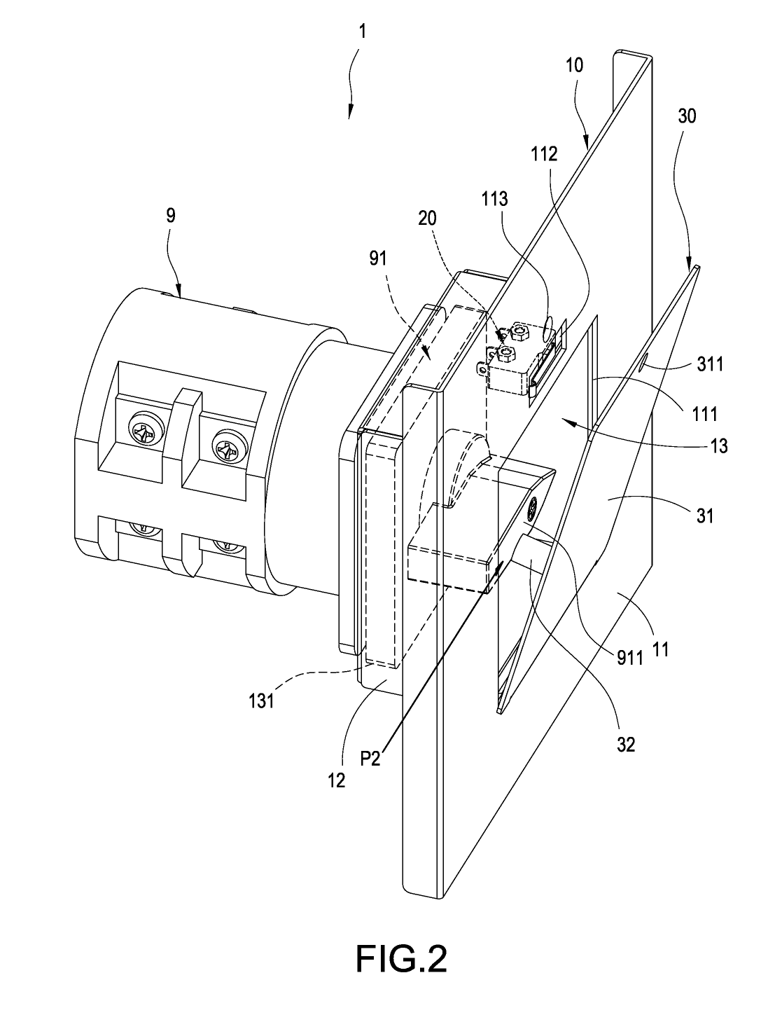

A side of a cabinet is provided as a chassis 10. The chassis 10 is composed of a supporting plate 11 and an enclosure 12. The supporting plate 11 has an opening 111, an installation hole 112, and a screw hole 113 (as shown in FIG. 2). The installation hole 112 is located between the opening 111 and the screw hole 113, and the enclosure 12 is extended from a periphery of the opening 111 of the supporting plate 11. The enclosure 12 has an opening slot 113 communicated with the opening 111, and the opening slot 113 has a port 131 away from a side of the supporting plate 11 (as shown in FIG. 2). The uninterruptible power supply device 9 is installed in the cabinet, and a switching piece 911 of the switch 91 is inserted in the opening slot 13 from the port 131. Moreover, the cabinet could be applied in electronic instrument or production equipment and so on.

The sensor 20 is inserted in the installation hole 112 of the supporting plate 11 and located on a side of the opening 111 of the supporting plate 11. The sensor 20 electrically connects with a power supply controlling module, and the power supply controlling module is electrically connected with the starting switch of the uninterruptible power supply device 9. Thus the sensor 20 electrically connects with the uninterruptible power supply device 9 by the power supply controlling module. The types of the sensor 20 could be, but not limited to, an infrared sensor or some other sensors having the same effects.

The cover body 30 includes a cover plate 31 and at least one blocking member 32. The cover plate 31 has a through hole 311 corresponded to the screw hole 113 of the supporting plate 11 (as shown in FIG. 2). The blocking member 32 is extended from a lateral side near the opening slot 13 of the chassis 10, and one side of the blocking member 32 away from the cover 31 can be inserted in the opening slot 13 of the chassis 10. The blocking member 32 can be embodied as, but not limited to a column, a hollow column or a bump etc. Furthermore, when the cover plate 31 covers the opening slot 13 of the chassis 10 and the switching piece 911 has changed from a first position P1 to a second position P2, the switching piece 911 will eject the blocking member 32 for that the switching piece 911 is aligned with the blocking member 32. In this way, the cover plate 31 will depart from the opening slot 13 to expose the opening slot 13.

The protecting structure 1 further includes a fastener 40. The fastener 40 is inserted in the through hole 311 of the cover plate 31 and screwed in the screw hole 113 of the supporting plate 11.Thus the cover plate 31 is fixed by the fastener 4. The fastener 40 is, for example, a screw.

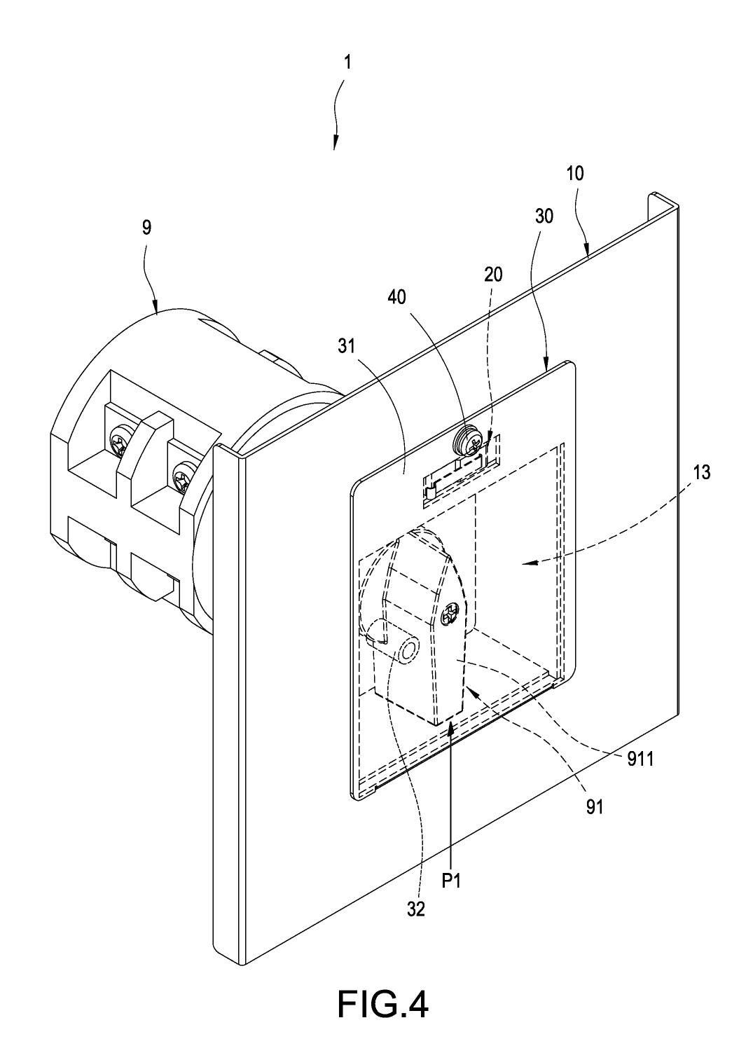

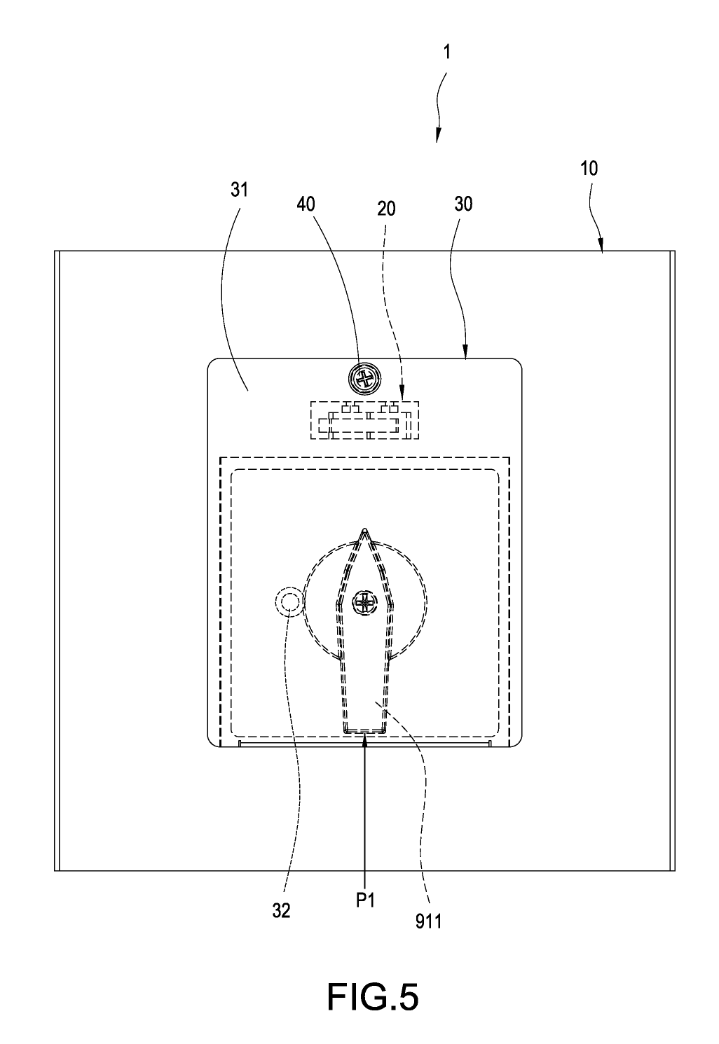

Please refer to FIG. 4 and FIG. 5, they depict two schematic views showing the operating state of a first embodiment of the present invention. When the uninterruptible power supply device 9 is switched from the second status to the first status and the switching piece 911 of the switch 91 locating at the first position P1 or the second position P2 is switched to the first position P1, the starting switch must be manipulated so that the uninterruptible power supply device 9 can switch from the second status to the first status.

In operation, the switching piece 911 of the switch 91 is pulled back from the second position P2 to the first position P1 at first. At the moment that the cover body 30 covers the chassis 10, the blocking member 32 is located on a side of the switching piece 911 and the cover plate 31 can cover the chassis 10. When the cover plate 31 covers the chassis 10, the sensor 20 will receive a detecting signal emitted from the sensor 20 and reflected from the cover plate 31. The sensor 20 transmits a signal to the power supply controlling module, and the power supply controlling module commands the starting switch in a workable state. Now the uninterruptible power supply device 9 can switch from a second status to a first status by manipulating the starting switch, and the power supply equipment will process a normal mode working.

By a design of the blocking member 32, the cover body 30 cannot cover the chassis 10 when the switching piece 911 of the switch 91 is in the second position P2. Thus users can be reminded that the uninterruptible power supply device 9 has not switched from the second status to a first status, and a foolproof effect and a faulty operation prevention for uses can be achieved.

In addition, a situation that the power supply equipment connecting with the uninterruptible power supply device 9 will provide electricity to the electronic instrument or production equipment through the normal loop status and the bypass loop status at the same time can be avoided. And a short circuit or a damage of the electronic instrument or production equipment will be caused when the switching piece 911 of the switch 91 is located in the second position P2 and the uninterruptible power supply device 9 is in the second status. Thus an effect for protecting the electronic equipment or production equipment can be achieved.

Moreover, by a design of the sensor 20, when the cover plate 31 does not cover the chassis 10, the starting switch is in a non-work state. When the cover plate 31 totally covers the chassis 10, the starting switch can be switched to a workable state because of the sensor 20.

Therefore, a situation that the power supply equipment connecting with the uninterruptible power supply device 9 will provide electricity to the electronic instrument or production equipment through the normal loop status and the bypass loop status at the same time can be avoided. And a short circuit or a damage of the electronic instrument or production equipment will happen when the switching piece 911 of the switch 91 is located in the second position P2 or a faulty operation of the starting switch is made by users. Thus an effect of protecting the electronic equipment or production equipment will be improved.

Furthermore, the sensor 20 can be provided separately with the uninterruptible power supply device 9 by disposing on the supporting plate 11 of the chassis 10. An uninterruptible power supply device 9 without a sensor 20 can be chosen, and the uninterruptible power supply device 9 will be cheaper for cost-saving. In another aspect, the switch 91 is covered in the opening slot 13 of the chassis 10 by the cover plate 31 covering the chassis 10. Hence the switch 91 and the uninterruptible power supply device 9 will keep clean and away from environment pollution. And an effect of protecting the electronic equipment or production equipment will be achieved.

A housing of a cabinet is provided as a chassis 10. The size of the electronic instrument or production equipment installed with the uninterruptible power supply device 9 will be reduced because the switch 91 is disposed in the opening slot 13 from the port 131 and the uninterruptible power supply device 9 is installed in the cabinet. Besides, since the cover plate 31 is screwed with the chassis 10 by the fastener 40, the cover plate 31 will not detach from the chassis 10 when the cover plate 31 suffers an external force.

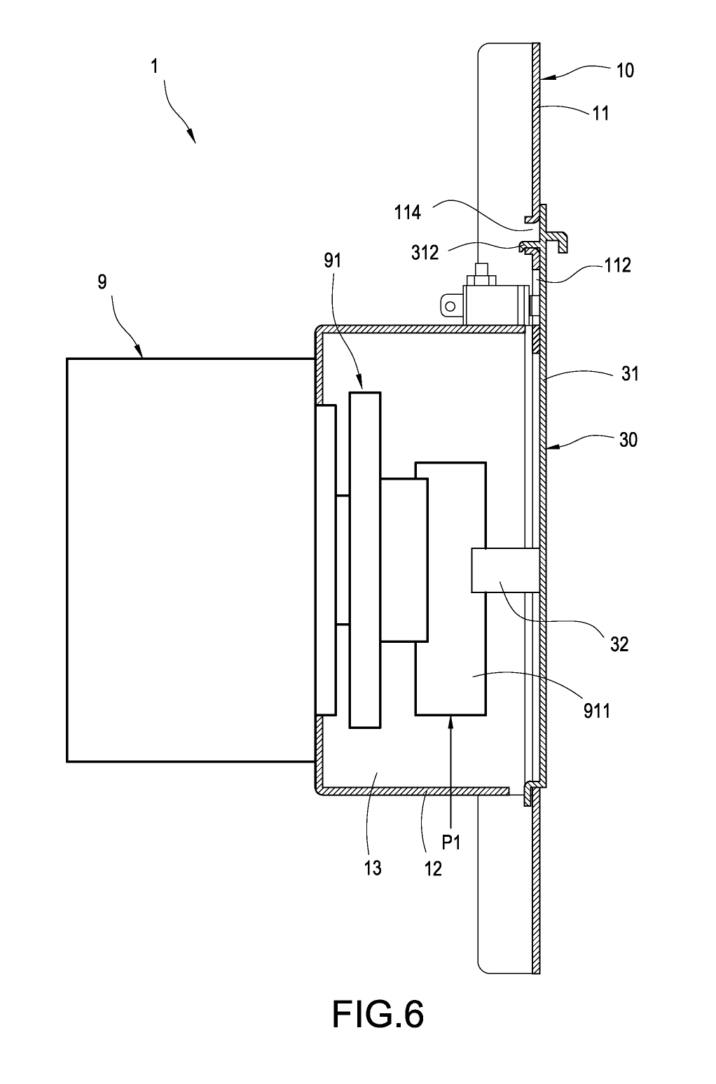

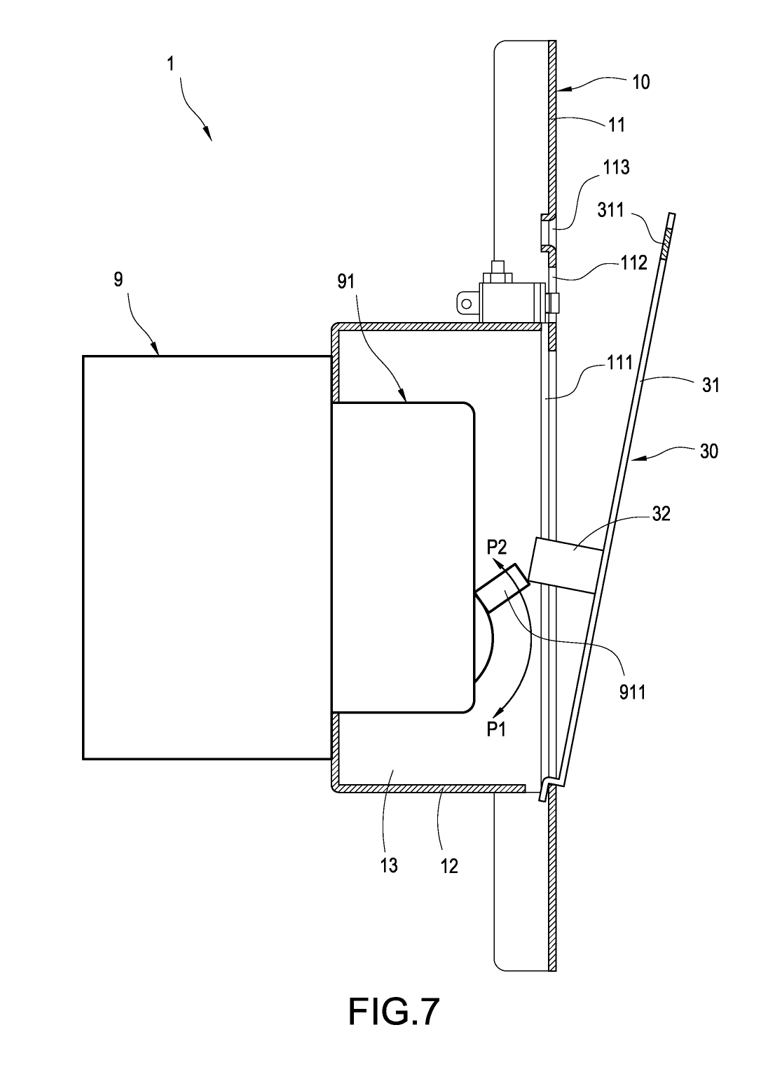

With referring to FIG. 6, it depicts a schematic view of a second embodiment of the present invention. This embodiment differs from the first embodiment in that the screw 113 of the supporting plate 11 is replaced with at least one engaging slot 114, and the through hole 311 of the cover plate 31 is replaced with at least one hook 312. The engaging slot 114 is provided on the supporting plate 11 of the chassis 10, and the installation hole 112 is located between the opening 111 (as shown in FIG. 7) and the engaging slot 114. The hook 312 is provided at a lateral side of the cover plate 31, and the hook 312 is latched in the engaging slot 114. The cover plate 31 will be fixed firmly in the chassis 10 by the hook 312 latched in the engaging slot 114. Hence the cover plate 31 will not detach from the chassis 10 when the cover plate 31 suffers an external force.

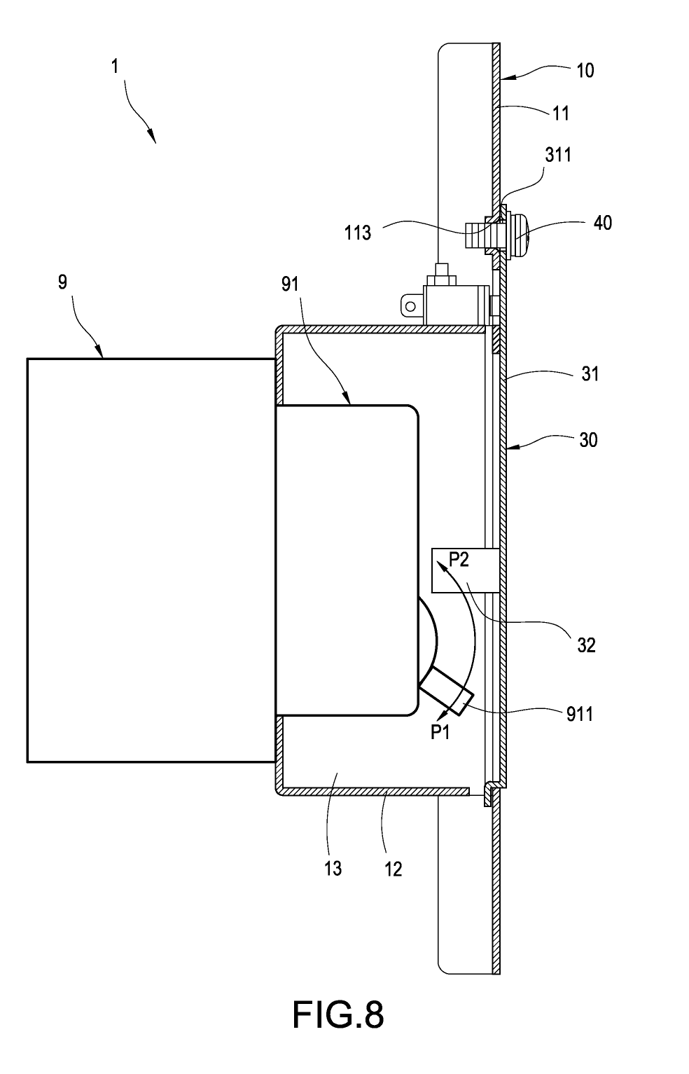

Please refer to FIG. 7 and FIG. 8, they depict two schematic views showing the operating state of a third embodiment of the present invention. This embodiment differs from the first embodiment in that the uninterruptible power supply device 9 is a circuit breaker, the switch 91 is a toggle switch, and the switching piece 911 is a trigger piece. When the switching piece 911 is pulled upward for switching from a first position P1 to a second position P2, the blocking member 32 will align and eject the switching piece 911, and then the cover plate 31 cannot cover the chassis 10. The switching piece 911 must be pulled downward to the first position P1 so that the blocking member 32 will locate on an upper side of the switching piece 911, thus the cover plate 31 can cover the chassis 10.

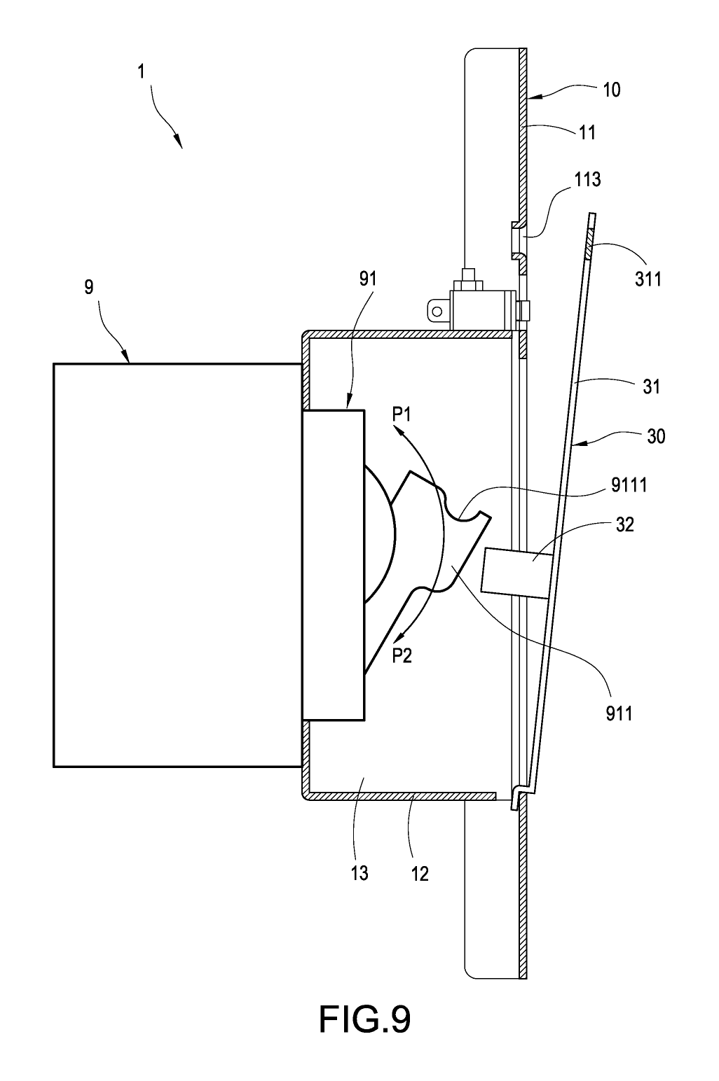

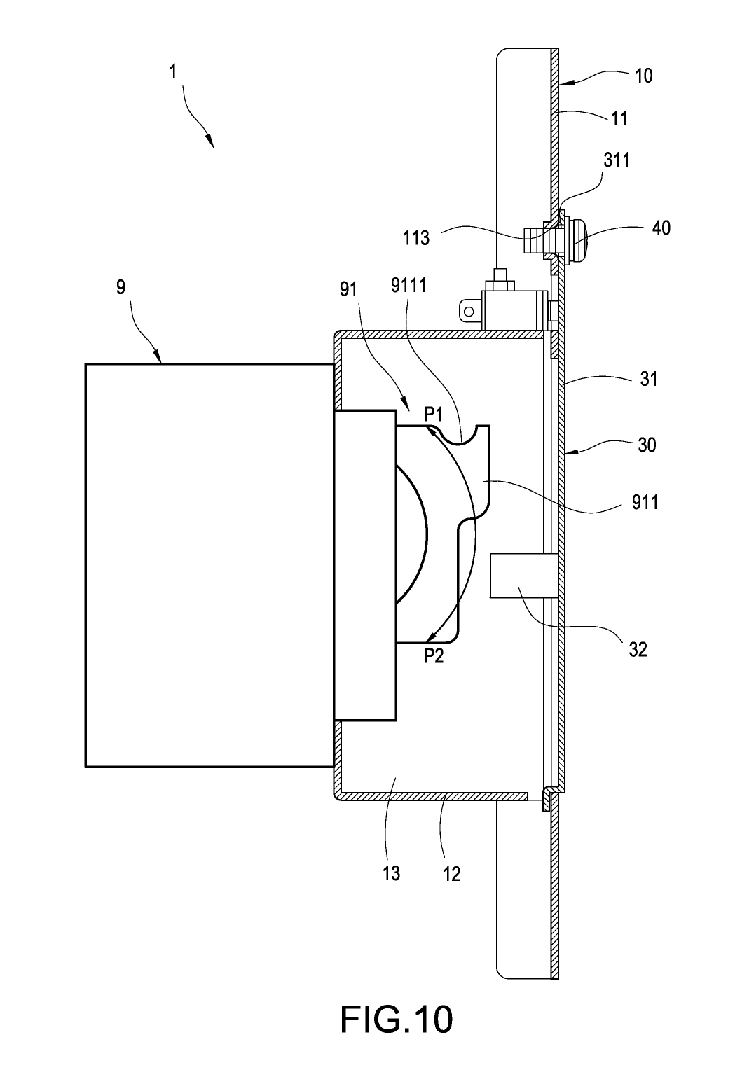

Please refer to FIG. 9 and FIG. 10, they depict two schematic views showing the operating state of a fourth embodiment of the present invention. This embodiment differs from the first embodiment in that the uninterruptible power supply device 9 is a fuse, the switch 91 is a lever switch, and the switching piece 911 is a lever. The switching piece 911 has a handing portion 9111. When the switching piece 911 is pulled downward for switching from a first position P1 to a second position P2, the blocking member 32 will align and eject the handing portion of the switching piece 911, and then the cover plate 31 cannot cover the chassis 10. The switching piece 911 must be pulled upward to the first position P1 so that the blocking member 32 will locate on a lower side of the handing portion of the switching piece 911, thus the cover plate 31 can cover the chassis 10.

Although the present invention has been described with reference to the preferred embodiment thereof, it will be understood that the invention is not limited to the details thereof. Various substitutions and improvements have been suggested in the foregoing description, and others will occur to those of ordinary skill in the art. Therefore, all such substitutions and improvements are intended to be embraced within the scope of the invention as defined in the appended claims.

What is claimed is:

1. A protecting structure of an uninterruptible power supply, the protecting structure used in a switch having a switching piece, the protecting structure comprising:
a chassis having an opening slot, the switch installed in the chassis and the switching piece disposed corresponding to the opening slot; and
a cover body including a cover plate and at least one blocking member connecting with the cover plate, the cover plate covering the opening slot, wherein the switching piece ejects the blocking member to expose the opening slot when the covered switching piece is switched from a first position to a second position.

2. The protecting structure according to claim 1, wherein the chassis is composed of a supporting with an opening and an enclosure extended from a peripheral of the opening, and the opening slot is surrounded by the enclosure.

3. The protecting structure according to claim 2, wherein the opening slot has a port away from a side of the supporting plate, and the switching piece is disposed on the opening slot from the port.

4. The protecting structure according to claim 2, further including a fastener, wherein the supporting plate has a screw hole located on a side of the opening, the cover plate has a through hole corresponding to the screw hole, and the fastener is inserted in the through hole for screwing in the screw hole.

5. The protecting structure according to claim 4, wherein the fastener is a screw.

6. The protecting structure according to claim 2, wherein the supporting plate has at least one engaging slot, and a periphery of a side of the cover plate has at least one hook corresponded to latch in the engaging slot.

7. The protecting structure according to claim 1, wherein the blocking member is a column extended from a lateral side of the cover plate near the opening slot.

8. The protecting structure according to claim 1, wherein the blocking member is a hollow column extended from a lateral side of the cover plate near the opening slot.

9. A protecting structure of an uninterruptible power supply, the protecting structure used in an uninterruptible power supply device having a switch with a switching piece, the protecting structure comprising:
a chassis having an opening slot, the uninterruptible power supply device installed in the chassis and the switching piece disposed correspondingly to the opening slot;
a sensor provided on a side of the opening slot of the chassis, the sensor electrically connecting with the uninterruptible power supply device; and
a cover body including a cover plate and at least one blocking member connecting with the cover plate, the cover plate covering the opening slot, wherein the switching piece ejects the blocking member to expose the opening slot when the covered switching piece is switched from a first position to a second position.

10. The protecting structure according to claim 9, wherein the chassis is composed of a supporting with an opening and an enclosure extended from a peripheral of the opening, and the opening slot is surrounded by the enclosure.

11. The protecting structure according to claim 10, wherein the opening slot has a port away from a side of the supporting plate, and the switching piece is disposed on the opening slot from the port.

12. The protecting structure according to claim 10, wherein the supporting plate has an installation hole provided on a side of the opening, and the sensor is inserted in the installation hole.

13. The protecting structure according to claim 10, further including a fastener, wherein the supporting plate has a screw hole located on a side of the opening, the cover plate has a through hole corresponding to the screw hole, and the fastener is inserted in the through hole for screwing in the screw hole.

14. The protecting structure according to claim 13, wherein the fastener is a screw.

15. The protecting structure according to claim 10, wherein the supporting plate has at least one engaging slot, and a periphery of a side of the cover plate has at least one hook corresponded to latch in the engaging slot.

16. The protecting structure according to claim 9, wherein the blocking member is a column extended from a lateral side of the cover plate near the opening slot.

17. The protecting structure according to claim 9, wherein the blocking member is a hollow column extended from a lateral side of the cover plate near the opening slot.
